(19) United States
(12) Patent Application Publication
(10) Pub. No.: US 2025/0022651 A1
(43) Pub. Date: Jan. 16, 2025

(54) ROGOWSKI COIL BASED BUSHING CURRENT TRANSFORMER

(71) Applicant: Accuenergy (Canada) Inc., Toronto (CA)

(72) Inventors: Vahid Behjat, Toronto (CA); Yufan Wang, Toronto (CA); Ketao Li, Toronto (CA); Liang Wang, Toronto (CA)

(73) Assignee: Accuenergy (Canada) Inc., Toronto (CA)

(21) Appl. No.: 18/221,406

(22) Filed: Jul. 13, 2023

(51) Int. Cl. H01F 27/42; H01F 27/24; H01F 27/28; H01F 27/33; H05K 1/18

(52) U.S. Cl. CPC H01F 27/427; H01F 27/24; H01F 27/28; H01F 27/33; H05K 1/185; H05K 2201/1003

(57) ABSTRACT

A Rogowski integrator kit, equipped with RJ45 socket, that provides simple installation and protection against Electromagnetic Interference (EMI) and Electrostatic Discharge (ESD). The kit consists of a Rogowski coil that comes with a first RJ45 socket and an electrical integrator that includes a second RJ45 socket. With these features, the Rogowski integrator kit ensures reliable and accurate measurement in a safe and secure manner.

### FIELD OF THE INVENTION

The present disclosure generally relates to a Rogowski coil based bushing current transformer.

### BACKGROUND OF THE INVENTION

A bushing current transformer (BCT) is a type of window current transformer 104 (FIG. 1) that is installed around the flange of a bushing. This transformer comprises a secondary winding 102 wrapped around a core 112, with the primary current passing through the core's opening 116. During the assembly process, the secondary winding 102 is wound around the core 112 before placing the assembly into a mold, where an insulating material is injected around the transformer. Taps 114 are brought out from the winding 102. A power line passes through the window 116 and acts as the primary source.

However, BCTs often suffer from issues related to inaccuracy and space limitations. The requirements for metering and protection CTs impose certain limitations on BCTs. Metering CTs need a smaller cross-section of the core to reduce magnetizing current and provide precise current measurements with high accuracy. On the other hand, protection CTs require a larger cross-section of the magnetic core to avoid saturation during high through fault currents, which can result in inaccurate measurements, especially for low amplitude currents. One possible solution to overcome these limitations is to design separate CTs for metering and protection purposes and combine them into one measurement package, which can then be mounted on the oil side of the bushing. However, this approach may intrude excessively into the tank, necessitating an increase in tank size.

Therefore, further improvements to the BCT would be desirable.

### SUMMARY OF THE INVENTION

The embodiments of the present disclosure generally related to a bushing current transformer.

In some embodiments, the Rogowski coil based bushing current transformer includes a top insulation layer, a bottom insulation layer, and a printed circuit board (PCB) Rogowski coil positioned between the top and bottom insulation layers. The PCB Rogowski coil is specifically designed with a circular cutout that allows it to easily and securely accommodate the flange of a power transformer bushing. The top and bottom insulation layers provide electrical isolation and protection for the PCB Rogowski coil, while the circular cutout in the coil facilitates simple and efficient installation onto the flange of the power transformer bushing.

This innovative design of the bushing current transformer enables it to function as both a metering current transformer (CT) and a protection CT, while also simplifying installation and reducing manufacturing costs. The improved accuracy and reliability of current measurement in high voltage power systems, combined with the ease of installation and cost-effective manufacturing, make this Rogowski coil based bushing current transformer a valuable and practical solution for current monitoring applications in power systems.

These and other features and aspects of the present disclosure will become fully apparent from the following detailed description of exemplary embodiments, the appended claims and the accompanying drawings.

### BRIEF DESCRIPTION OF THE DRAWINGS

FIG. 1 is a disassembled view of a conventional window current transformer.

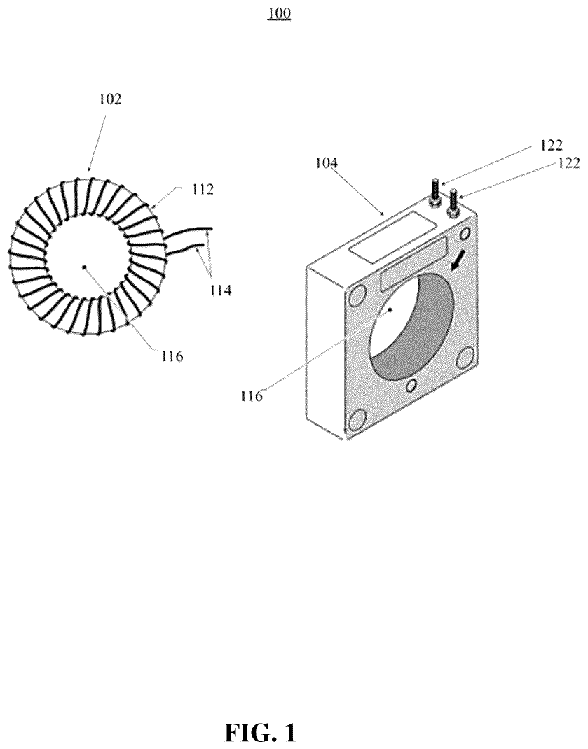

FIG. 2 is a perspective view of a Rogowski coil based bushing current transformer according to some embodiments of the present invention.

FIG. 3 is an exploded view of a Rogowski coil based bushing current transformer according to some embodiments of the present invention.

FIG. 4 is a schematic diagram illustrating an exemplary adaptive noise cancellation circuit according to some embodiments of the present invention.

### DETAIL DESCRIPTIONS OF THE INVENTION

Embodiments of the present disclosure will be described herein with reference to the accompanying drawings. In the following descriptions, well-known functions or constructions are not described in detail to avoid obscuring the present disclosure. The word “exemplary” is used herein to mean “serving as an example.” Any configuration or design described herein as “exemplary” is not to be construed as preferred, or advantageous, over other configurations or designs. Herein the phrase “coupled” is defined as “directly connected to or indirectly connected with” one or more intermediate components. Such intermediate components may include both hardware and software-based components.

It is further noted that, unless otherwise indicated, all functions described herein may be implemented in either software, hardware, or some combination thereof.

It should be recognized that the present disclosure can be performed in numerous ways, including as a process, an apparatus, a system, a method, or a computer-readable medium such as a computer storage medium.

BCTs are commonly utilized for metering and protection. The applications of BCT protection includes restricted earth fault (REF) protection, and winding temperature indicator (WTI) in transformers. REF protection is used to detect internal earth faults in the transformer, while WTI is used to indicate the hot spot temperature of the winding based on thermal imaging technique.

BCTs face challenges with accuracy and space. At low currents, the iron core's exciting current can cause ratio errors that are predominant until sufficient primary magnetic flux overcomes the effects of core magnetizing. Measurements taken at very low loads may have substantial errors from both ratio error and phase shift.

Exciting current errors are dependent on the construction of individual CTs. Protection CTs generally have higher exciting current effects compared to metering CTs due to their design. Metering CTs are designed with core cross sections chosen to minimize the effects of exciting current, and their cores are allowed to saturate at fault currents. On the other hand, protection CTs use larger cores to avoid high current saturation and faithfully reproduce high currents for fault sensing. The exciting current of the larger core at low primary current is not considered important for protection, but it can be a problem for measuring low currents. To meet the requirements of both metering and protection CTs, the BCT should come with at least two cores or compromise some performance indicators. One solution could be to design separate coils for metering and protection, but this may cause space constraints as there is limited space between the active part of the transformer and the tank to restrict flux leakage.

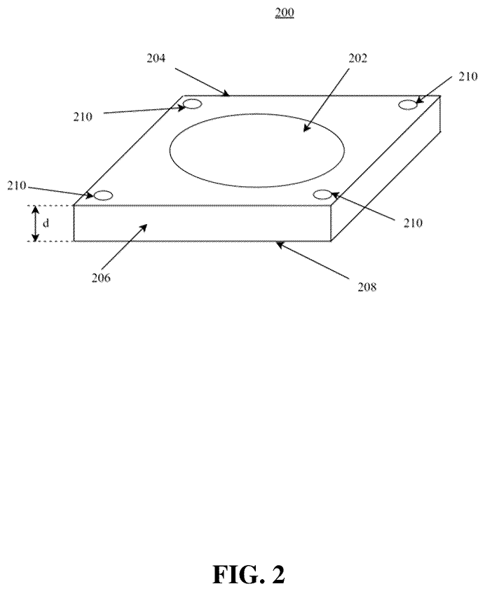

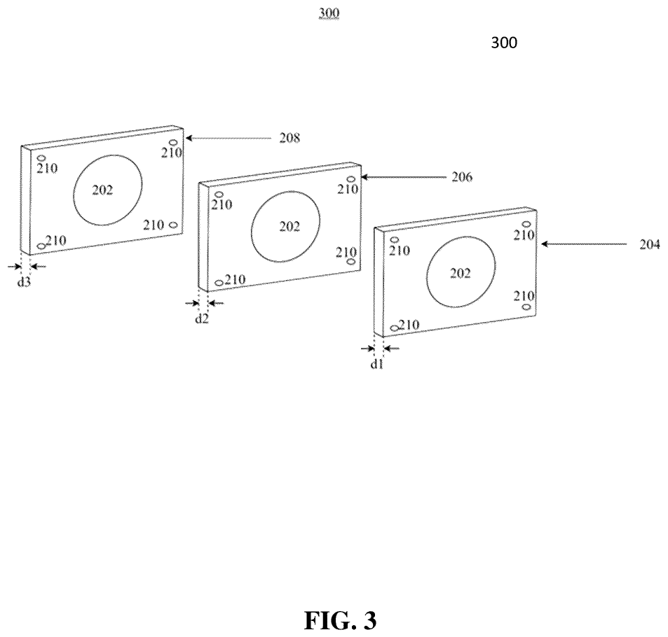

To address the issues with traditional bushing current transformers (accuracy and space), this invention proposes a Rogowski coil based BCT illustrated in FIG. 2 and FIG. 3, which can be mounted on the turret on the oil side of the bushing according to some embodiments of the present invention. Turrets are raised structures on the top of the transformer, usually round in section, to which the bushing flange is mounted.

BCT 200 comprises a circular cutout 202, a top insulation layer 204, a bottom insulation layer 208, and a printed circuit board (PCB) Rogowski coil 206 positioned between the top and bottom insulation layers. The circular cutout 202 is designed to be slightly smaller than the flange of the bushing, allowing the BCT 200 to be mounted in the flange for easy installation. In some embodiments, the BCT 200 may be square, while in other embodiments, it may be round or have other appropriate shapes. In some embodiments, the top insulation layer 204, the bottom layer 208 and the PCB Rogowski coil 206 have the same shape as illustrated in FIG. 3, while in other embodiments, they may have different shapes.

The top insulation layer 204 and the bottom insulation layer 208 should be made of cellulose-based or polyester-based materials, serving as the main insulation for the BCT 200.

BCT 200 further includes a plurality of holes 210 that are strategically positioned to allow for fasteners to secure the PCB Rogowski coil 206 to both the top insulation layer 204 and the bottom insulation layer 208. This enables the BCT 200 to be easily mounted on the oil side of the bushing, ensuring optimal performance.

In some embodiments, the coil is implemented by rectilinear metal deposit on each of the two faces of PCB Rogowski coil 206 and extending along radii such that geometrical projections thereof intersect in the center of the cutout 202. The electrical connections between the radii on one face and those on the opposite face are implemented by plated through holes that pass through the thickness d2 of PCB Rogowski coil 206. The coil turns on PCB Rogowski coil 206 are evenly spaced, minimizing the risk of positional inaccuracies.

Compared to traditional current transformers with magnetic cores, Rogowski coils offer several advantages, such as non-saturation, high measurement accuracy, wide measurement range, simple fabrication technique, and low cost. In recent years, Rogowski coils have become extremely popular for measuring current in power grids and are widely used to measure three-phase current in circuit breaker space. However, Rogowski coils can face issues with position inaccuracy, low mutual inductance, and phase angle difference. The use of integral circuitry can address the issue of phase angle difference, but Rogowski coils with low mutual inductance may have low signal-to-noise ratio and be vulnerable to interference from external magnetic fields. Therefore, the design of Rogowski coils with large mutual inductance and integral circuitry is required.

The mutual inductance M for the Rogowski coil, assuming ideal coil with no gap between the ends can be calculated according to the following formula:

$$M = N \times \frac{μ \times h}{2 \times π} \times ln \frac{b}{a}$$

where N is number of turns, h is the thickness of the printed circuit board, μ is the permeability of air, a is the inside diameter of Rogowski coil, b is the a is the outside diameter of Rogowski coil. Mutual inductance can be enhanced by increasing coil turns, thickness of the printed circuit board and the ratio of outer to inner diameter.

The thickness d2 of PCB Rogowski coil 206 is advantageously equal to 5 mm for an enhanced mutual inductance. The thickness d1 of the top insulation layer 204 is advantageously equal to 1 mm. The thickness d2 of the bottom insulation layer 208 is advantageously equal to 1 mm.

As there is fixed turn spacing and fixed location of the primary conduct, there is no positional inaccuracy due to uneven turn spacing and eccentricity of the primary conductor. Furthermore, due to no air-gap at the coil structure, there is no positional sensitivity as a result of turn discontinuity at coil ends. The invented solution provides a cost-effective and high-performance solution for internally mounted bushing current transformers.

The ability of the invented PCB Rogowski Bushing in providing both unsaturated protection measurement as well as winding current measurement is of great importance. Since the measured current controls fan, and motor pump control as well as high-temperature warning alarm and trip circuit contact. On the other hand, unsaturated performance is very important for REF.

In one embodiment, the Rogowski coil based bushing current transformer (BCT) as previously described is further enhanced by integrating an adaptive noise cancellation circuit 400 within the printed circuit board (PCB) Rogowski coil. This adaptive circuitry 400 is designed to significantly mitigate the effects of external electromagnetic interference (EMI), which is a common issue in environments where high electrical currents and magnetic fields are present. By improving the signal-to-noise ratio, the adaptive noise cancellation circuit 400 ensures that the current measurements are more accurate and reliable, particularly in electrically noisy environments.

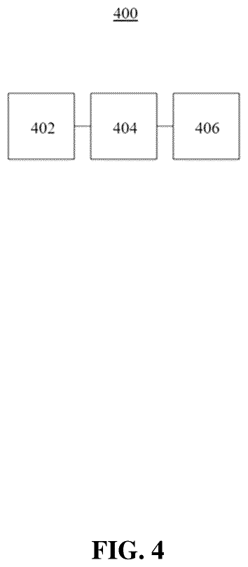

Referring to FIG. 4, the adaptive noise cancellation circuit 400 primarily includes three main components: a reference input sensor 402, an adaptive filter 404, and a subtractor 406.

The reference input sensor 402 is designed to detect the noise component which is presumed to be part of the signal measured by the Rogowski coil. This sensor can be an auxiliary coil or any other type of sensor capable of measuring electromagnetic interference. It's important that this sensor does not substantially pick up the desired signal (current being measured), but mainly picks up the noise which is to be cancelled.

The adaptive filter 404 is the core component of the noise cancellation circuit. It takes the input from the reference input sensor and processes it in real time. The adaptive filter has adjustable parameters that get tuned automatically, often using algorithms like the Least Mean Squares (LMS). It models the noise in such a way that it can be subtracted from the signal containing both the desired measurement and the noise.

The subtractor 406 takes two inputs; one is the output from the adaptive filter 404 (which is the modeled noise), and the other is the signal output from the PCB Rogowski coil 206 which contains both the desired signal and the noise. The subtractor 406 then subtracts the modeled noise from the mixed signal. This results in an output which is a cleaner version of the desired signal, having substantially reduced the noise component.

The adaptive nature of the filter means that it continuously adjusts its parameters to best model the noise. This is crucial in environments where the characteristics of noise might change with time.

This integration of adaptive noise cancellation within the PCB Rogowski coil can be achieved with minimal increase in physical dimensions and can be powered by an independent source. Moreover, the integration is done in such a way that it does not alter the fundamental operation of the Rogowski coil; it only enhances the quality of the measurements.

In practical applications, such as in substations or industrial environments, where there are numerous sources of EMI, the inclusion of the adaptive noise cancellation circuit can be the difference between obtaining measurements that are usable and reliable versus measurements that are drowned in noise and unusable. This innovation, thus, significantly broadens the applicability and reliability of the Rogowski coil-based bushing current transformer in real-world applications.

In another embodiment, the Rogowski coil based bushing current transformer (BCT) as previously described is further refined by incorporating a temperature-sensitive material or component within the printed circuit board (PCB) Rogowski coil. This incorporation is aimed at allowing the BCT to not only measure current but also detect and monitor the temperature of the transformer windings. Such temperature monitoring is vital for the implementation of thermal protection schemes and optimizing the efficiency and lifespan of the transformer.

The temperature-sensitive material or component that is integrated into the PCB Rogowski coil is designed to alter its electrical properties in response to changes in temperature. Two primary types of temperature-sensitive components that can be used in this context are thermistors and Resistance Temperature Detectors (RTDs).

Thermistors are semiconductor devices that exhibit a large, predictable change in resistance as the temperature changes. There are two types of thermistors: Negative Temperature Coefficient (NTC) thermistors, where resistance decreases as temperature increases, and Positive Temperature Coefficient (PTC) thermistors, where resistance increases as temperature increases. In this embodiment, thermistors can be embedded within or in close proximity to the PCB Rogowski coil. The change in their resistance with temperature can be measured and correlated to the temperature of the transformer windings.

RTDs are temperature sensors that utilize the predictable change in electrical resistance of certain materials with changing temperature. Typically made of pure platinum, RTDs provide very accurate temperature readings over a wide range. Similar to thermistors, RTDs can be embedded within or in close proximity to the PCB Rogowski coil.

The integration of either thermistors or RTDs into the PCB Rogowski coil should be done in a manner that allows for efficient thermal coupling with the transformer windings, ensuring that the temperature-sensitive component accurately reflects the temperature of the windings.

Additionally, the BCT must include circuitry to interpret the changes in electrical properties of the temperature-sensitive component and convert it into temperature data. This circuitry can be integrated into the existing electronics of the BCT or be a separate module.

The temperature data collected can be used for various purposes including, but not limited to:

Triggering alarms if the temperature exceeds certain thresholds, indicating a potential fault or dangerous operating condition.

Modulating the cooling systems of the transformer in real-time to maintain optimal operating temperatures.

Providing data for predictive maintenance and efficiency optimization algorithms.

By integrating temperature sensing capability directly into the PCB Rogowski coil, this embodiment of the Rogowski coil based bushing current transformer becomes a multifunctional device that can monitor both current and temperature. This enhances the transformer's protection schemes and contributes to prolonging its operational life and efficiency. Furthermore, it reduces the need for separate temperature monitoring devices, thus saving space and reducing complexity.

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

1. A Rogowski coil based bushing current transformer comprising:
a top insulation layer,
a bottom insulation layer,
and a printed circuit board (PCB) Rogowski coil positioned between the top insulation layer and the bottom insulation layer, the PCB Rogowski coil having a circular cutout for accommodating the flange of a power transformer bushing.

2. The Rogowski coil based bushing current transformer of claim 1, wherein at least one of the top insulation layer and the bottom insulation layer is made of cellulose-based or polyester-based materials.

3. The Rogowski coil based bushing current transformer of claim 1, wherein the coil turns on the PCB Rogowski coil are evenly spaced.

4. The Rogowski coil based bushing current transformer of claim 1, further comprising an adaptive noise cancellation circuit integrated within the PCB Rogowski coil.

5. The Rogowski coil based bushing current transformer of claim 1, wherein the PCB Rogowski coil includes at least one of a temperature-sensitive material and a component that alters its electrical properties based on the temperature.
